(19) United States
(12) Patent Application Publication
(10) Pub. No.: US 2025/0054760 A1
(43) Pub. Date: Feb. 13, 2025

(54) CARBON MASK DEPOSITION

(71) Applicant: Lam Research Corporation, Fremont, CA (US)

(72) Inventors: Daniela ANJOS RIGSBY, Tualatin, OR (US); Kapu Sirish REDDY, Portland, OR (US); Todd SCHROEDER, Sherwood, OR (US)

(21) Appl. No.: 18/717,677

(22) PCT Filed: Jan. 10, 2023
(86) PCT No.: PCT/US2023/060364

§ 371 Date: Jun. 7, 2024

Related U.S. Application Data
(60) Provisional application No. 63/266,670, filed on Jan. 11, 2022.

(51) Int. Cl. H01L 21/033; C23C 16/02; C23C 16/04; C23C 16/26; C23C 16/455; C23C 16/505; H01J 37/32; H10B 12/00; H10B 41/20; H10B 43/20

(52) U.S. Cl. CPC H01L 21/0337; C23C 16/0227; C23C 16/042; C23C 16/26; C23C 16/45565; C23C 16/505; H01J 37/32174; H01L 21/0332; H10B 12/01; H10B 41/20; H10B 43/20; H01J 2237/3321; H01J 2237/3327

(57) ABSTRACT

Examples are disclosed that relate to depositing a carbon mask to thicken a partially etched mask. One example provides a method comprising forming a mask layer on a substrate, and etching the substrate to partially form one or more etched features, the etching of the substrate also causing etching of the mask layer. The method further comprises, after etching a portion of the one or more etched features but before completing etching of the one or more etched features, depositing, by plasma-enhanced chemical vapor deposition (PECVD), a carbon mask over the mask layer.

### BACKGROUND

Semiconductor device fabrication processes can involve the etching of high aspect ratio structures. For example, the fabrication of three-dimensional memory structures involves forming high aspect ratio channel holes by etching.

### SUMMARY

Examples are disclosed that relate to depositing a carbon mask to thicken a partially etched mask. One example provides a method comprising forming a mask layer on a substrate, and etching the substrate to partially form one or more etched features, the etching of the substrate also causing etching of the mask layer. The method further comprises, after etching a portion of the one or more etched features but before completing etching of the one or more etched features, depositing, by plasma-enhanced chemical vapor deposition (PECVD), a carbon mask over the mask layer.

Alternatively or additionally, in some such examples, depositing the carbon mask over the mask layer comprises forming a plasma comprising a carbon-containing compound, argon, and molecular nitrogen.

Alternatively or additionally, in some such examples, the carbon-containing compound comprises one or more of an alkane, an alkene, or an alkyne.

Alternatively or additionally, in some such examples, the carbon-containing compound comprises one or more of a cyclic hydrocarbon, an aromatic, an alcohol, an aldehyde, an ester, an ether, a ketone, an alkyl halide, or an alkyl amine.

Alternatively or additionally, in some such examples, the plasma comprises a higher frequency radiofrequency power component and a lower frequency radiofrequency power component, the lower frequency radiofrequency power component comprising a lower frequency than the higher frequency radiofrequency power component.

Alternatively or additionally, in some such examples, the plasma further comprises a hydrogen source.

Alternatively or additionally, in some such examples, the method further comprises heating the substrate to a temperature within a range of 100 to 690 degrees Celsius.

Alternatively or additionally, in some such examples, the carbon mask is deposited without the use of a patterning step.

Alternatively or additionally, in some such examples, the substrate comprises a substrate in a three-dimensional NAND memory fabrication process, a substrate in a three-dimensional NOR memory fabrication process, or a substrate in a three-dimensional DRAM fabrication process.

Alternatively or additionally, in some such examples, the carbon mask is deposited in a single deposition step.

Another example provides a method, comprising obtaining a substrate comprising one or more etched features and a partially etched mask layer, and exposing the substrate to a plasma comprising a carbon-containing compound and an inert gas to deposit a carbon mask over the partially-etched mask layer without use of a patterning step.

Alternatively or additionally, in some such examples, the plasma further comprises a hydrogen source.

Alternatively or additionally, in some such examples, the carbon-containing compound comprises one or more of an alkane, an alkene, an alkyne, a cyclic hydrocarbon, an aromatic, an alcohol, an aldehyde, an ester, an ether, a ketone, an alkyl halide, or an alkyl amine.

Alternatively or additionally, in some such examples, the inert gas comprises argon.

Alternatively or additionally, in some such examples, the plasma comprises a higher frequency radiofrequency energy component and a lower frequency radiofrequency energy component, the lower frequency radiofrequency energy component having a lower frequency than the higher frequency radiofrequency energy component.

Another example provides a processing tool. The processing tool comprises a processing chamber. The processing tool further comprises a substrate support disposed within the processing chamber. The processing tool further comprises a substrate heater disposed within the processing chamber. The processing tool further comprises a showerhead disposed within the processing chamber. The processing tool further comprises a radiofrequency power supply configured to supply radiofrequency power to the showerhead or the substrate support. The processing tool further comprises flow control hardware configured to control gas flow from a carbon-containing compound source and an inert gas source into the processing chamber through the showerhead. The processing tool further comprises a controller operatively coupled to the flow control hardware and the substrate heater. The controller is configured to operate the substrate heater to heat a substrate disposed in the processing chamber. The controller is further configured to operate the flow control hardware to introduce a carbon-containing compound gas from the carbon-containing compound source into the processing chamber. The controller is further configured to operate the flow control hardware to introduce an inert gas from the inert gas source into the processing chamber. The controller is further configured to operate the radiofrequency power supply to supply a lower frequency radiofrequency energy component and a higher frequency radiofrequency energy component to form a plasma comprising the carbon-containing compound gas and the inert gas to grow a carbon mask on a partially etched mask without use of a patterning step, the lower frequency radio frequency energy component comprising a lower frequency than the higher frequency radiofrequency energy component.

Alternatively or additionally, in some such examples, the first radiofrequency energy component comprises a power within a range of 500-2500 W, and the second radiofrequency energy component comprises a power within a range of 800-2500 W.

Alternatively or additionally, in some such examples, the processing tool further comprises the carbon-containing compound source, wherein the carbon-containing compound source comprises one or more of an alkane, an alkene, an alkyne, a cyclic hydrocarbon, an aromatic, an alcohol, an aldehyde, an ester, an ether, a ketone, an alkyl halide, or an alkyl amine.

Alternatively or additionally, in some such examples, the carbon-containing compound source comprises acetylene.

Alternatively or additionally, in some such examples, the processing tool further comprises the inert gas source, wherein the inert gas comprises argon.

### BRIEF DESCRIPTION OF THE DRAWINGS

FIGS. 1A-1E schematically show various example substrate structures formed during an example process for etching a high aspect ratio feature.

FIGS. 2A-2B show a flow diagram depicting an example method for forming a carbon mask over a partially etched mask.

FIG. 3 schematically shows an example plasma enhanced chemical vapor deposition tool.

FIG. 4 shows a block diagram of an example computing system.

### DETAILED DESCRIPTION

The term “alcohol” generally represents compounds comprising a general formula R—OH, where R is an unsubstituted, partially substituted or fully substituted aryl or aliphatic group. Alcohols can have more than one OH group (polyols), such as diols, which have two OH functional groups. Example alcohols comprise methanol, ethanol, and propanol.

The term “aldehyde” generally represents organic compounds comprising a terminal carbonyl group. Aldehydes have the general formula R—CHO, where R is an unsubstituted, partially substituted or fully substituted aryl or aliphatic group. Example aldehydes comprise formaldehyde and acetaldehyde.

The term “aliphatic” generally represents organic compounds lacking aromatic groups.

The term “alkane” generally represents organic compounds comprising a general formula CₙH₂ₙ₊₂, and partially substituted or fully substituted variants thereof Example alkanes include methane, ethane, propane, and butane.

The term “alkene” generally represents organic compounds comprising at least one carbon-carbon double bond, including unsubstituted, partially substituted, and fully substituted variants thereof. Unsubstituted alkenes comprising one carbon-carbon double bond have a general formula of CₙH₂ₙ. Example alkenes include ethylene, propylene, and butylenes. Alkenes can have more than one carbon-carbon double bond, such as dienes, allenes, and cumulenes.

The term “alkyl amine” generally represents hydrocarbon compounds comprising a nitrogen with 1 to 3 alkyl substituents (including unsubstituted, partially substituted, and fully substituted alkyl substituents) and 0 to 2H substituents. Alkyl amines comprise primary, secondary, tertiary, and cyclic amines. Examples of alkyl amines include methylamine, dimethylamine, trimethylamine, and piperidine. Alkyl amines include compounds with two or more amine groups.

The term “alkyl halide” generally represents alkane, alkene, and alkyne compounds comprising a halogen. Examples of alkyl halides comprise ethyl fluoride (fluoroethane), isopropyl bromide (2-bromopropane), and t-butyl chloride (2-chloro-2-methylpropane). Alkyl halides can have two or more halogen groups, such as 1,2-dichlorobutane.

The term “alkyne” generally represents organic compounds comprising at least one carbon-carbon triple bond, including partially substituted or fully substituted variants thereof. Unsubstituted alkynes comprising one carbon-carbon triple bond have a general formula of CₙH₂ₙ₋₂. Alkynes can have more than one carbon-carbon triple bond, such as diynes, which have two carbon-carbon triple bonds.

The term “aromatic” generally represents a planar cyclic compound comprising pi bonding in resonance. The term “aromatic” comprises homocyclic compounds in which all atoms in a ring structure are carbon, and also heterocyclics in which one or more atoms in a ring structure are elements other than carbon (e.g. nitrogen).

The term “carbon-containing compound” generally represents a molecular substance comprising carbon atoms. Example carbon-containing compounds that can be used for forming a carbon mask in a PECVD process may include various alkanes, alkenes, alkynes, cyclic hydrocarbons, aromatics, alcohols, aldehydes, esters, ethers, ketones, aldehydes, alkyl halides, and alkyl amines.

The term “carbon mask” generally represents a layer of carbon formed on a substrate. A carbon mask can comprise amorphous carbon in some examples. Amorphous carbon can have nanoscale crystallites comprising both sp² and sp³ carbon.

The term “chemical vapor deposition” (“CVD”) generally represents a process in which a film of a substance is formed on a substrate by exposure of the substrate to one or more volatile precursors. The term “plasma enhanced CVD” (“PECVD”) generally represents a process in which a plasma is used to generate reactive species from the precursors for deposition.

The term “cyclic hydrocarbon” generally represents saturated and unsaturated hydrocarbon molecules comprising a closed ring structure, including partially or fully substituted variants thereof. Example cyclic hydrocarbons include aliphatic hydrocarbons such as cyclopropane and cyclobutane, as well as aromatic hydrocarbons such as benzene, toluene, xylene, and pyridine.

The term “ether” generally represents carbon-containing compounds having the general formula R—O—R′ where R and R′ are independently an unsubstituted, partially substituted or fully substituted aryl or aliphatic group. Example ethers comprise diethyl ether, methyl phenyl ether, and cyclic ethers such as furan.

The term “ester” generally represents hydrocarbon compounds comprising the general formula R—C(O)OR′ where R and R′ are independently an unsubstituted, partially substituted or fully substituted aryl or aliphatic group, and wherein R can alternatively comprise H (e.g., formate). Examples esters comprise ethyl formate, methyl acetate, and ethyl acetate.

The term “intermediate structure” generally represents a structure formed by earlier processing steps that is modified in later processing steps.

The term “ketone” generally represents organic compounds comprising a non-terminal carbonyl. Ketones have the general formula R—C(O)—R′ where R and R′ are independently an unsubstituted, partially substituted or fully substituted aryl or aliphatic group. Example ketones comprise acetone and methyl ethyl ketone.

The term “mask loss” generally represents the loss of material from a mask layer during an etching process.

The term “patterning step” generally represents a photolithographic process.

The term “process chamber” generally represents an enclosure in which chemical and/or physical processes are performed on substrates. The pressure, temperature and atmospheric composition within a process chamber can be controllable to perform chemical and/or physical processes.

The term “processing tool” generally represents a machine including a process chamber and other hardware configured to enable processing to be carried out in the process chamber.

The term “sticking coefficient” generally represents a fraction of gas-phase species that adsorb to a substrate surface compared to a number of the gas-phase species that impinge upon the substrate surface.

The term “substrate” generally represents any object on which a film can be deposited.

The term “substrate support” generally represents any structure for supporting a substrate in a process chamber.

As mentioned above, semiconductor device fabrication processes can involve the etching of high aspect ratio structures. For example, the fabrication of three-dimensional memory structures can involve etching high aspect ratio channel holes. One example of such a memory structure is three dimensional (3D) NAND memory, which is based upon a NOT AND logic gate architecture. Another example is 3D NOR memory, which is based upon a NOT OR logic gate architecture. High aspect ratio structures also can be formed during fabrication of a 3D-DRAM (dynamic random access memory) device.

To protect surrounding structures from damage when etching a feature into a substrate, a mask layer can be deposited and patterned to cover the surrounding structures. However, etching a high aspect ratio structure can also etch the mask, causing thinning of the mask. This can be referred to as mask loss. Mask loss can impact the outcome of an etching process. For example, mask loss can lead to difficulties in maintaining target dimensions in an etched feature.

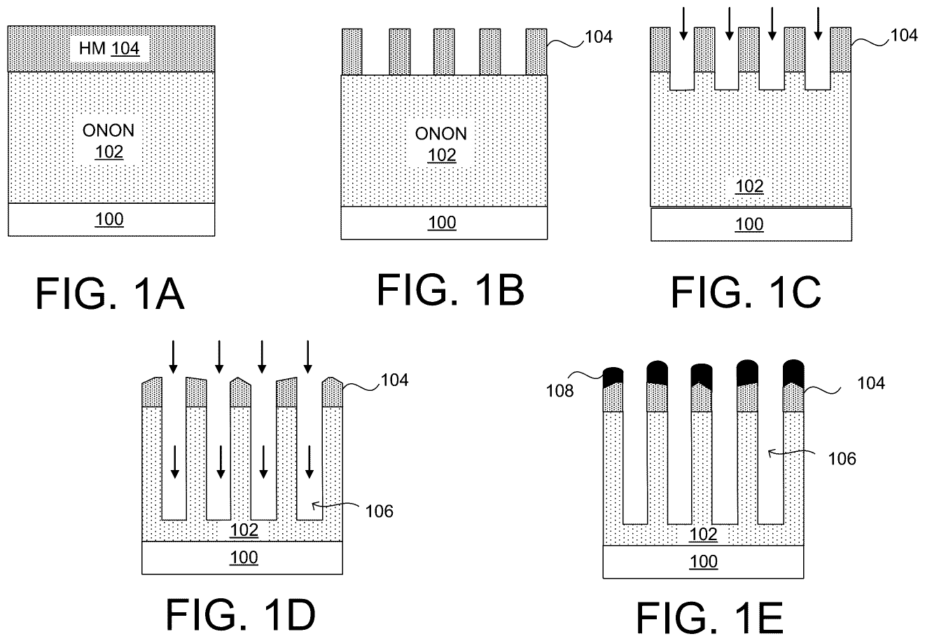

As a more specific example, in a 3D NAND memory fabrication process, a stack of alternating layers of a first material and a second material is formed. In some examples, the stack of alternating layers can comprise alternating silicon oxide and polysilicon layers. In other examples, the stack of alternating layers can comprise alternating silicon oxide and silicon nitride layers. FIG. 1A shows a schematic depiction of an example substrate 100 on which a stack 102 of alternating silicon oxide and silicon nitride layers (represented by the label “ONON”) has been formed. Further, a hard mask layer 104 has been formed over stack 102. FIG. 1A thus represents an intermediate structure in a 3D NAND fabrication process. Substrate 100 represents any suitable structures over which stack 102 can be formed. Likewise, hard mask layer 104 can be formed from any suitable material. In some examples, hard mask layer 104 comprises amorphous carbon.

To form 3D memory structures, the hard mask layer 104 is patterned, and then high aspect ratio channel holes are etched at least partially through stack 102. The intermediate structure of FIG. 1B illustrates the hard mask layer 104 after patterning. The patterning steps used to define the locations of the channel holes are not shown herein. Referring next to the intermediate structure of FIG. 1C, the etching process forms channel holes 106 through hard mask layer 104 and into stack 102. Downwardly pointed arrows indicate a directional etching process. Example directional etching processes include reactive ion etching (RIE), sputtering, and ion milling. Hard mask layer 104 protects adjacent regions of stack 102 from damage during the etching process, thereby helping to maintain target dimensions for the channel holes.

However, as mentioned above, channel holes 106 can have a relatively high aspect ratio. For example, the aspect ratio can be on the order of 20 to 100 in some examples. In view of the depth of the etch, hard mask layer 104 can suffer mask loss during the etching process. The mask loss results in thinning of hard mask layer 104, as illustrated by the intermediate structure depicted in FIG. 1D. This can affect the dimensions of the channel holes being etched. It will be understood that mask loss similarly can occur when etching other high aspect ratio features than channel holes for 3D memory devices.

Accordingly, examples are disclosed that relate to the growth of a carbon mask layer over another mask layer (e.g. an amorphous carbon hard mask) at an intermediate point in an etching process to recover at least some mask thickness that was lost during etching. FIG. 1E illustrates a carbon mask layer 108 formed over the thinned hard mask layer 104. The growth of carbon mask layer 108 at an intermediate point during an etching process can help to retain target dimensions for channel holes 106 during the subsequent portion of the etching process. Carbon mask layer 108 can be deposited at any suitable intermediate point in an etching process. In some examples, a single carbon mask layer 108 can be deposited during an etching process. In other examples, two or more depositions of carbon mask layers can be performed at two or more different intermediate points in an etching process to recover lost thickness, and thereby maintain a desired total mask layer thickness.

Carbon mask layer 108 can be deposited in a single cycle, with no patterning steps. For example, deposition of a carbon mask by PECVD using both a lower frequency radiofrequency (RF) power component and a higher frequency RF power component can result in carbon mask formation on a top surface of a hard mask layer with little to no carbon being deposited within the etched features. The terms “lower frequency” and “higher frequency” are relative to one another. In some examples, the lower frequency RF power component can have a frequency of less than 2 MHz, and the higher frequency RF power component can have a frequency of 2 MHz or greater. In other examples, the lower and higher frequency RF power components can have any other suitable values. In one experiment utilizing a lower frequency RF power component and a higher frequency RF power component, a single-step carbon deposition process was used to grow a carbon mask on a hard mask over a partially etched ONON stack. The hard mask had a post-etch thickness of 793.7 nanometers. A carbon mask was grown on the hard mask to a total thickness (hard mask layer plus carbon mask layer) of 977.3 nanometers. The carbon mask layer was deposited by PECVD using an argon plasma. Acetylene was used as a carbon-containing compound. In some examples, a hydrogen source (e.g. molecular hydrogen) also can be used during the carbon mask deposition process. After carbon mask formation, the channel holes appeared to be free of carbon. Without wishing to be bound by theory, the sticking coefficient of the carbon-containing compound under processing conditions, combined with etching by argon ions in the plasma, may contribute to carbon preferentially depositing on the top surfaces of the hard mask layer, and not depositing on walls of the feature being etched. The use of the lower frequency RF power component together with the higher frequency RF power component may provide for a greater degree of etching than the use of the higher frequency RF power component alone. This is because the addition of the lower frequency RF power component may cause a greater degree of argon ion bombardment of the substrate than the use of the higher frequency RF power component alone. This may help to remove previously deposited carbon the walls of the feature at a higher rate than a rate at which carbon deposits on the walls, thereby preventing net carbon growth on the walls.

In other examples, carbon mask layer 108 can be formed in multiple steps. For example, separate PECVD carbon deposition and etching steps can be used. In such an example, a carbon-containing compound can be introduced into a plasma in a carbon deposition step. Then, an argon etching step can be used to remove carbon. As a vertical growth rate of carbon on the partially etched mask may be higher than a horizontal growth rate on the walls of the feature being etched, the etching step can remove carbon from the walls of the feature being etched while still allowing for net vertical growth of carbon on the partially etched mask.

Any suitable carbon-containing compound can be used as a carbon source to deposit a carbon mask as disclosed herein. Examples of carbon-containing compounds can include alkanes having a general formula CₙH₂ₙ₊₂ where n=1 to 10 (such as, methane, ethane, etc.), alkenes having a general formula CₙH₂ₙ where n=2 to 10 (such as, ethylene, propylene, etc.), alkynes having a general formula CₙH₂ₙ₋₂ where n=2 to 10 (such as, acetylene, propyne, etc.), partially or fully substituted variants thereof, and other carbon-containing compounds that are in a gaseous phase under processing conditions. Examples can include cyclic hydrocarbons (aliphatic and aromatic), alcohols, aldehydes, esters, ethers, ketones, alkyl halides, and alkyl amines. In still other examples, the carbon-containing compound can comprise a mixture of carbon-containing compounds. Example of suitable cyclic hydrocarbons can include cyclobutane, cyclopentane and cyclohexane. Example of suitable aromatics can include benzene, toluene, pyridine, and pyrimidine. Example of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Example of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, piperidine, ethylenediamine and 1,3-diaminopropane.

Likewise, any suitable processing conditions can be used to form a carbon mask as disclosed. In some examples, a carbon mask can be formed using PECVD, with argon and molecular nitrogen (N₂) as plasma gases, and a carbon-containing compound as a source of carbon for mask deposition. In some examples, a hydrogen source can be used along with argon, molecular nitrogen, and the carbon-containing compound. Example hydrogen sources include molecular hydrogen and ammonia. Without wishing to be bound by theory, hydrogen can act as a passivating agent to reduce a rate of carbon film formation on surfaces to which the hydrogen is adsorbed. The hydrogen, in combination with etching from impact by energetic argon ions, can help to favor vertical carbon growth over lateral carbon growth. Further, the carbon mask can have a higher growth rate in a vertical direction (upwards from the partially etched mask) than in a horizontal direction (normal to a sidewall of a feature being etched). The combination of the lower horizontal growth rate, the hydrogen passivation, and the etching by argon ions, can help avoid carbon deposition on surfaces within the partially etched features while growing the carbon mask vertically. Further, in some examples, carbon dioxide also can be used as a gas during PECVD deposition of a carbon film according to the present disclosure.

Suitable RF powers for the plasma include a higher frequency RF power within a range of 800-2500 W (watts), and a lower frequency RF power of 500-2500 W. In other examples, a single RF frequency can be used to form the plasma. Suitable substrate temperatures include temperatures within a range of 100-690 degrees Celsius. Suitable gas flow rates include a flow rate between 500-700 standard cubic centimeter per minute (sccm) of carbon-containing compound (e.g. acetylene), flow rates between 8000-12,000 sccm of argon, and flow rates of 0-2000 sccm of molecular nitrogen. Lower flow rates of the carbon-containing compound can result in lower deposition rates, but also can help smooth roughness of the hard mask layer surface. Such gas flow rates can be used to maintain any suitable pressure within a processing chamber. Examples include pressures between 1-20 Torr. In some examples, other gases also can be used during carbon mask deposition. Examples include helium. These or other suitable process conditions can be used to form a carbon mask of any suitable thickness. Example thickness include thicknesses within a range of 200-600 nm. In other examples, any other suitable conditions can be used to grow a carbon mask of any other suitable thickness.

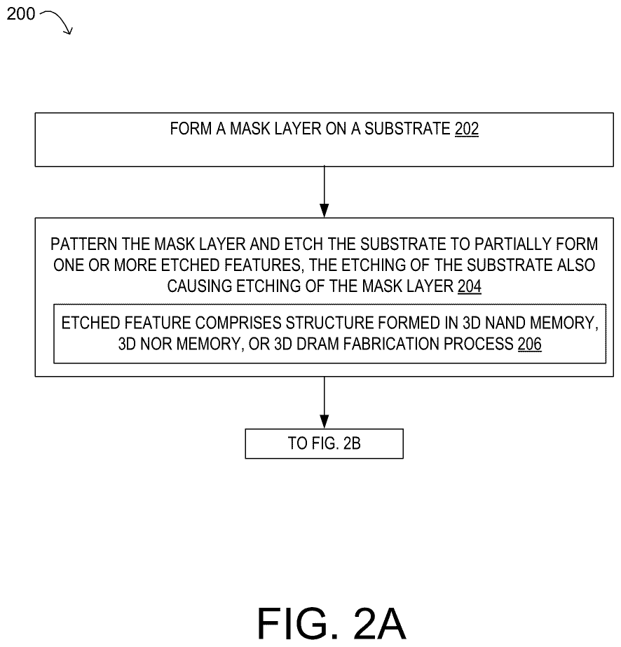

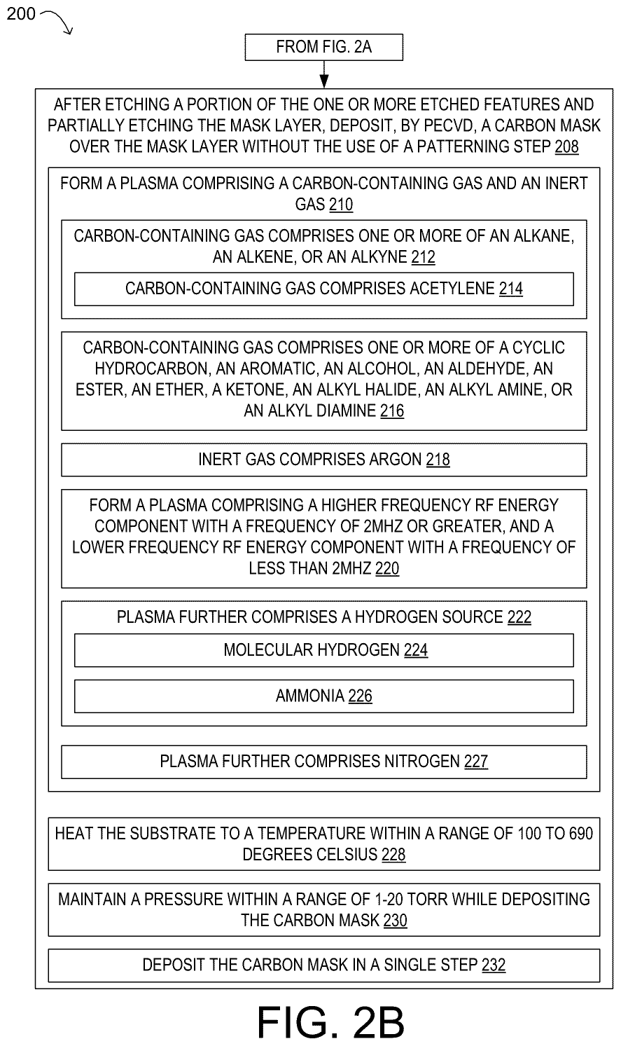

FIGS. 2A-2B shows a flow diagram depicting an example method 200 for processing a substrate that involves depositing a carbon mask over a partially etched mask layer. First referring to FIG. 2A, method 200 comprises, at step 202, forming a mask layer on a substrate. The mask layer can comprise a carbon hardmask in some examples.

Method 200 further comprises, at step 204, patterning the mask layer and etching the substrate to partially form one or more etched features. The etching of the substrate also causes etching of the mask layer at a slower rate than the etching of the substrate. Thus, the mask layer is partially etched during the etching process. In some examples, the one or more etched features comprises a structure formed in a 3D NAND memory, 3D NOR memory, or 3D DRAM fabrication process, as indicated at 206. As a more specific example, the one or more etched features can comprise a channel hole formed in a 3D NAND memory fabrication process.

As mentioned above, the mask loss caused by the etching of the mask layer can affect the dimensions of the channel holes being etched. Thus, referring next to FIG. 2B, at step 208, method 200 comprises, after etching a portion of the one or more etched features and partially etching the mask layer, depositing, by plasma-enhanced chemical vapor deposition (PECVD), a carbon mask over the mask layer without use of a patterning step. Depositing the carbon mask can comprise, at 210, forming a plasma comprising a carbon-containing compound and argon. Various carbon-containing compounds can be used. Generally, carbon-containing compounds that are gas-phase under processing chamber conditions and that do not contain undesirable elements may potentially be used to form a carbon mask. Examples of carbon-containing compounds that can be used to deposit a carbon mask include one or more of an alkane, an alkene, or an alkyne, as indicated at 212. A more specific example is acetylene, as indicated at 214. In other examples, the carbon-containing compound comprises one or more of a cyclic hydrocarbon, an aromatic, an alcohol, an aldehyde, an ester, an ether, a ketone, an alkyl halide, or an alkyl amine, as indicated at 216.

As indicated at 218, in some examples, the inert gas can comprise argon. In other examples, another suitable inert gas can be used in the plasma. Examples include helium, neon, krypton, and xenon. Further, in some examples, molecular nitrogen gas can be used as an inert gas where the plasma conditions do not form reactive nitrogen species from the molecular nitrogen gas.

As mentioned above, in some examples, the plasma comprises a higher frequency RF power component with a frequency of 2 MHz or greater, and a lower frequency RF power component with a frequency of less than 2 MHz. The use of the lower frequency RF power component together with the higher frequency RF power may provide for higher etch rates that remove carbon from surfaces within a feature being etched more efficiently than the use of the higher frequency RF power alone. The growth rate of the carbon mask in a vertical direction upwardly from the substrate can be higher than the growth rate of the carbon mask horizontally within the partially etched features on the substrate. Thus, net vertical growth of the carbon mask can occur, while carbon that deposits within the partially etched features is substantially removed.

In some examples, the plasma at 210 can further comprise a hydrogen source molecule, at 222. As described above, hydrogen may act as a passivant that adsorbs to surfaces on the substrate, including surfaces within the partially etched features. Hydrogen radicals and other reactive hydrogen-containing species can be formed in the plasma, and adsorb to surfaces on the substrate. This can lower the rate of carbon deposition, thereby further helping to prevent carbon from depositing within the partially etched features. Examples of suitable hydrogen sources include molecular hydrogen 224 and ammonia 226. Further, in some examples, molecular nitrogen (N₂) can be used as an additional gas in the plasma, as indicated at 227.

Any suitable processing conditions can be used during carbon mask growth. In some examples, the substrate can be heated to a temperature within a range of 100 to 690 degrees Celsius, as indicted at step 228. Further, in some examples, a total pressure within the processing chamber can be maintained within a range of 1-20 Torr while depositing the carbon mask, as indicated at 230. As other example processing conditions, suitable RF powers for the plasma can include a higher frequency RF power within a range of 800-2500 W, and a lower frequency RF power of 500-2500 W. Suitable gas flow rates include a flow rate between 500-700 standard cubic centimeter per minute (sccm) of carbon-containing compound (e.g. acetylene), and flow rates between 8000-12,000 sccm of argon. Lower flow rates of the carbon-containing compound can result in lower deposition rates, but also can help smooth roughness of the carbon mask layer surface. These or other suitable process conditions can be used to form a carbon mask of any suitable thickness. Example thickness include thicknesses within a range of 200-600 nm. In other examples, any other suitable conditions can be used to grow a carbon mask of any other suitable thickness. As mentioned above, such processing conditions can be used to form a carbon mask on a partially etched mask in a single deposition step, at 232. In other examples, a carbon mask can be formed on a partially etched mask using one or more alternating deposition/etching cycles.

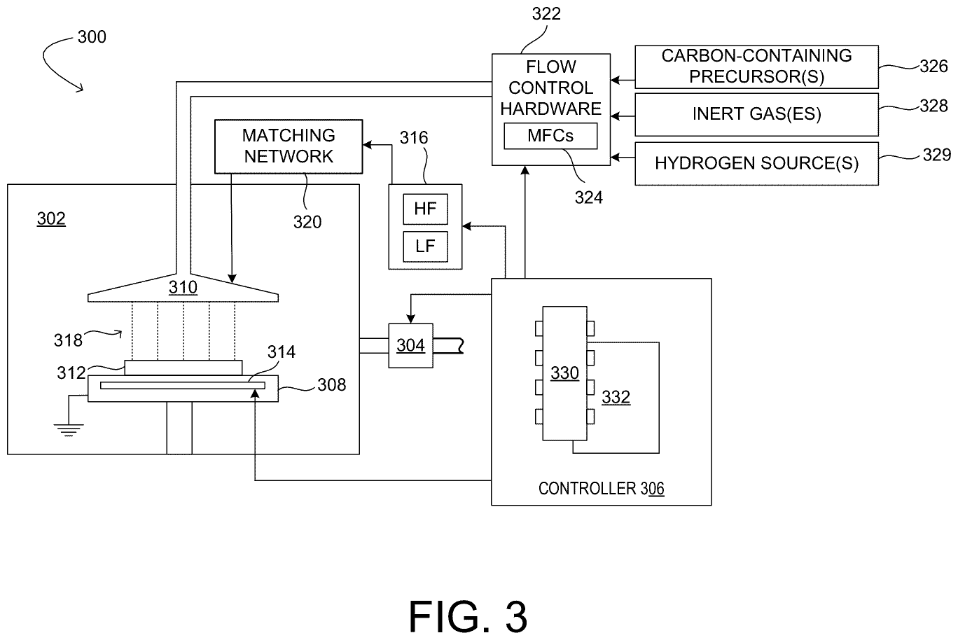

FIG. 3 shows an example processing tool 300 that can be used to perform a mask recovery by carbon mask deposition according to the present disclosure. Processing tool 300 can be used to perform method 200, for example. It will be understood that processing tool 300 is illustrative and not limiting, as other suitable tools can be used to practice the example methods disclosed herein.

Processing tool 300 takes the form of a PECVD tool comprising a deposition chamber 302. Deposition chamber 302 is configured to be maintained at a reduced pressure during deposition processes via a vacuum pump system 304 comprising one or more pumps. Vacuum pump system 304 is in electrical communication with a controller 306 configured to output control signals to vacuum pump system 304 and other components described below.

A substrate holder 308 and showerhead 310 are arranged within deposition chamber 302. A substrate 312 is shown as arranged on substrate holder 308. Substrate holder 308 comprises a heater 314. The heater 314 is controlled via control signals from controller 306, so as to maintain the substrate holder 308 at a desired setpoint temperature.

Substrate holder 308 is connected to electrical ground, and showerhead 310 is connected to a power supply 316. Power supply 316 is configured to apply RF power to showerhead 310 to form a plasma within a discharge gap 318 between substrate holder 308 and showerhead 310. Power supply 316 receives control signals from the controller 306 to control various aspects of the current driven. In some examples, power supply 316 can be configured to supply RF power of multiple frequencies. For example, power supply 316 can be configured to supply RF power within a higher frequency (HF) band comprising one or more frequencies of 2 megahertz (MHz) or greater. Power supply 316 also can be configured to supply RF power within a lower frequency (LF) band comprising frequencies less than 2 MHz. The RF current driven through the discharge gap 318 by power supply 316 supports a carbon-depositing plasma. Processing tool 300 further comprises a matching network 320 disposed between power supply 316 and showerhead 310 for impedance matching of the RF power supply. In other examples, RF power can be supplied to substrate holder 308, and showerhead 310 can be connected to ground.

Processing tool 300 further comprises flow control hardware 322 configured to flow a mixture of gases though deposition chamber 302 at reduced pressure. Flow control hardware 322 can comprise, for example, mass-flow controllers 324 each of which provides a metered flow of a corresponding gas, as controlled by control signals from controller 306. As mentioned above, the gases metered by flow control hardware 322 include one or more carbon-containing compound(s) 326. Examples of carbon-containing compounds include alkanes having a general formula CₙH₂ₙ₊₂ where n=1 to 10 (such as, methane, ethane, etc.), alkenes having a general formula CₙH₂ₙ where n=2 to 10 (such as, ethylene, propylene, etc.), alkynes having a general formula CₙH₂ₙ₋₂ where n=2 to 10 (such as, acetylene, propyne, etc.), partially or fully substituted variants thereof and other carbon-containing compounds that are in a gaseous phase under processing conditions. Examples can include cyclic hydrocarbons (aliphatic and aromatic), alcohols, aldehydes, esters, ethers, ketones, alkyl halides, and alkyl amines. In still other examples, the carbon-containing compound can comprise a mixture of carbon-containing compounds. Example of suitable cyclic hydrocarbons can include cyclobutane, cyclopentane and cyclohexane. Example of suitable aromatics can include benzene, toluene, pyridine, and pyrimidine. Example of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Example of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, piperidine, ethylenediamine and 1,3-diaminopropane.

The gases metered by flow control hardware 322 also comprise one or more inert gas(es) 328, such as argon. Examples of other inert gases include helium (He) and, in some processing conditions, molecular nitrogen (N₂). The gases metered by flow control hardware 322 further can comprise one or more hydrogen source(s) 329, such as molecular hydrogen (H₂) or ammonia (NH₃).

As mentioned above, controller 306 of processing tool 300 is coupled operatively to vacuum pump system 304, heater 314, mass flow controllers 324, power supply 316, as well as to other controllable components of the processing tool 300. Controller 306 comprises at least one processor 330 and memory 332. Memory 332 holds instructions executable by the at least one processor 330 to direct controller 306 to enact any of the control functions associated with the fabrication processes disclosed herein, among other functions. In some examples, controller 306 can be local to other components of processing tool 300. In other examples, controller 306 can be located remotely to other components of processing tool 300. In yet other examples, controller 306 can be distributed between local and remote locations with reference to processing tool 300.

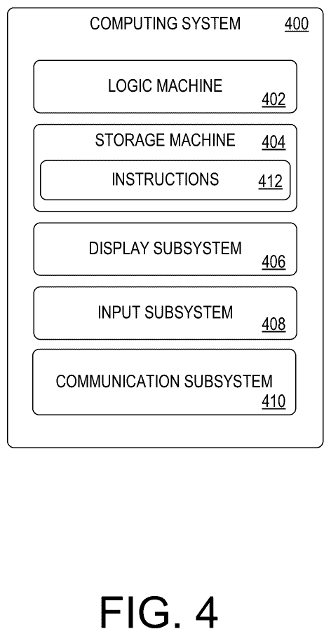

FIG. 4 schematically shows a example of a computing system 400 that can enact one or more of the processes described above. Computing system 400 is shown in simplified form. Computing system 400 can take the form of one or more personal computers, workstations, computers integrated with wafer processing tools, and/or network accessible server computers. Controller 306 is an example of computing system 400.

Computing system 400 includes a logic machine 402 and a storage machine 404. Computing system 400 can optionally include a display subsystem 406, input subsystem 408, communication subsystem 410, and/or other components not shown in FIG. 4.

Logic machine 402 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 404 includes one or more physical devices configured to hold instructions 412 executable by the logic machine to implement the methods and processes described herein. When such methods and processes are implemented, the state of storage machine 404 can be transformed—e.g., to hold different data.

Storage machine 404 can include removable and/or built-in devices. Storage machine 404 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 404 can include volatile, nonvolatile, dynamic, static, read/write, read-only, random-access, sequential-access, location-addressable, file-addressable, and/or content-addressable devices.

It will be appreciated that storage machine 404 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 402 and storage machine 404 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 406 can be used to present a visual representation of data held by storage machine 404. This visual representation can take the form of a graphical user interface (GUI). As the herein described methods and processes change the data held by the storage machine, and thus transform the state of the storage machine, the state of display subsystem 406 can likewise be transformed to visually represent changes in the underlying data. Display subsystem 406 can include one or more display devices utilizing virtually any type of technology. Such display devices can be combined with logic machine 402 and/or storage machine 404 in a shared enclosure, or such display devices can be peripheral display devices.

When included, input subsystem 408 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 410 can be configured to communicatively couple computing system 400 with one or more other computing devices. Communication subsystem 410 can include wired and/or wireless communication devices compatible with one or more different communication protocols. As examples, the communication subsystem can be configured for communication via a wireless telephone network, or a wired or wireless local- or wide-area network. In some examples, the communication subsystem can allow computing system 400 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

It will be understood that the configurations and/or approaches described herein are exemplary in nature, and that these specific examples or examples are not to be considered in a limiting sense, because numerous variations are possible. The specific routines or methods described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method, comprising:
forming a mask layer on a substrate;
etching the substrate to partially form one or more etched features, the etching of the substrate also causing etching of the mask layer; and
after etching a portion of the one or more etched features and partially etching the mask layer, depositing, by plasma-enhanced chemical vapor deposition (PECVD), a carbon mask over the mask layer.

2. The method of claim 1, wherein depositing the carbon mask over the mask layer comprises forming a plasma comprising a carbon-containing compound, argon and molecular nitrogen.

3. The method of claim 2, wherein the carbon-containing compound comprises one or more of an alkane, an alkene, or an alkyne.

4. The method of claim 2, wherein the carbon-containing compound comprises one or more of a cyclic hydrocarbon, an aromatic, an alcohol, an aldehyde, an ester, an ether, a ketone, an alkyl halide, or an alkyl amine.

5. The method of claim 2, wherein the plasma comprises a higher frequency radiofrequency power component and a lower frequency radiofrequency power component, the lower frequency radiofrequency power component comprising a lower frequency than the higher frequency radiofrequency power component.

6. The method of claim 2, wherein the plasma further comprises a hydrogen source.

7. The method of claim 1, further comprising heating the substrate to a temperature within a range of 100 to 690 degrees Celsius.

8. The method of claim 1, wherein the carbon mask is deposited without the use of a patterning step.

9. The method of claim 1, wherein the substrate comprises a substrate in a three-dimensional NAND memory fabrication process, a substrate in a three-dimensional NOR memory fabrication process, or a substrate in a three-dimensional dynamic random access memory (DRAM) fabrication process.

10. The method of claim 1, wherein the carbon mask is deposited in a single deposition step.

11. A method, comprising:
obtaining a substrate comprising one or more etched features and a partially etched mask layer; and
exposing the substrate to a plasma comprising a carbon-containing compound and an inert gas to deposit a carbon mask over the partially etched mask layer without use of a patterning step.

12. The method of claim 11, wherein the plasma further comprises a hydrogen source.

13. The method of claim 11, wherein the carbon-containing compound comprises one or more of an alkane, an alkene, an alkyne, a cyclic hydrocarbon, an aromatic, an alcohol, an aldehyde, an ester, an ether, a ketone, an alkyl halide, or an alkyl amine.

14. The method of claim 11, wherein the inert gas comprises argon.

15. The method of claim 11, wherein the plasma comprises a higher frequency radiofrequency energy component and a lower frequency radiofrequency energy component, the lower frequency radiofrequency energy component having a lower frequency than the higher frequency radiofrequency energy component.

16. A processing tool, comprising:
a processing chamber;
a substrate support disposed within the processing chamber;
a substrate heater disposed within the processing chamber;
a showerhead disposed within the processing chamber;
a radiofrequency power supply configured to supply radiofrequency power to the showerhead or the support;
flow control hardware configured to control gas flow from a carbon-containing compound source and an inert gas source into the processing chamber through the showerhead; and
a controller operatively coupled to the flow control hardware and the substrate heater, the controller configured to
operate the substrate heater to heat a substrate disposed in the processing chamber,
operate the flow control hardware to introduce a carbon-containing compound gas from the carbon-containing compound source into the processing chamber,
operate the flow control hardware to introduce an inert gas from the inert gas source into the processing chamber; and
operate the radiofrequency power supply to supply a lower frequency radiofrequency energy component and a higher frequency radiofrequency energy component to form a plasma comprising the carbon-containing compound gas and the inert gas to grow a carbon mask on a partially etched mask without use of a patterning step, the lower frequency radio frequency energy component comprising a lower frequency than the higher frequency radiofrequency energy component.

17. The processing tool of claim 16, wherein the lower frequency radiofrequency energy component comprises a power within a range of 500-2500 W, and the higher frequency radiofrequency energy component comprises a power within a range of 800-2500 W.

18. The processing tool of claim 16, further comprising the carbon-containing compound source, wherein the carbon-containing compound source comprises one or more of an alkane, an alkene, an alkyne, a cyclic hydrocarbon, an aromatic, an alcohol, an aldehyde, an ester, an ether, a ketone, an alkyl halide, or an alkyl amine.

19. The processing tool of claim 18, wherein the carbon-containing compound source comprises acetylene.

20. The processing tool of claim 16, further comprising the inert gas source, wherein the inert gas comprises argon.
